(19) United States
(12) Patent Application Publication
(10) Pub. No.: US 2009/0258507 A1
(43) Pub. Date: Oct. 15, 2009

(54) Substrate Treatment Device and Substrate Treatment Method

(76) Inventors: Takeshi Itoh, Toyama (JP); Kazuyuki Toyoda, Toyama (JP); Yuji Takebayashi, Toyama (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 11/991,354

(22) PCT Filed: Mar. 2, 2007
(86) PCT No.: PCT/JP2007/054044

§ 371 Date: Apr. 22, 2008

(30) Foreign Application Priority Data
Mar. 6, 2006 (JP) 2006-059241

(51) Int. Cl. H01L 21/263; C23C 16/513

(52) U.S. Cl. 438/798; 118/723 R; 257/E21.331

(57) ABSTRACT

In order to solve the problem of contamination caused by static electricity on the surface of a substrate after plasma treatment, the invention provides a substrate treatment device comprising a standby chamber in which is arranged a transfer device for loading a substrate out of/into a cassette rack accommodating a substrate, said substrate treatment device capable of retaining said substrate transferred by the transfer device in a boat and loading, by way of a boat elevator, the boat into/out of a treatment furnace capable of applying plasma treatment to said substrate, wherein a static eliminator for eliminating static electricity of said substrate is arranged in said standby chamber.

### TECHNICAL FIELD

The present invention relates to a substrate treatment device and a substrate treatment method capable of eliminating static electricity on a substrate loaded into a standby chamber after treatment of the substrate.

### BACKGROUND ART

There is known a semiconductor manufacturing device as a substrate treatment device for treating substrates by using plasma. Use of plasma aims to enable substrate treatment at a low temperature by way of ionization of gasses or acceleration of radical reaction thus preventing damage to a substrate caused by a higher temperature.

A vertical batch treatment device is known as a device utilizing plasma. One specific example is substrate treatment device where electrodes capable of applying a high frequency are arranged on the entire circumference alternately in the shape of a stripe between a soaking tube and a reaction tube thus turning a gas in the reaction tube into plasma. The gas tuned into plasma changes into ions, electrons or radicals, which react on the surface of a substrate and are formed into a film.

### DISCLOSURE OF THE INVENTION

Problems that the Invention is to Solve

When non-reacting ions or electrons are present on the substrate surface while the gas is tuned into plasma and formed into a film, such non-reacting ions or electrons are charged on the substrates. Now the substrate is charged with static electricity. In case impurities are included in the atmosphere surrounding the substrate, the static electricity could absorb the impurities thus contaminating the substrate.

While static elimination is available when the substrate charged with static electricity is grounded, a boat in which a substrate is loaded is typically made of quartz. Quartz is an insulating body so that currents are unlikely to flow into the ground thus making static elimination difficult. Quartz having the insulating property is a cause of electrostatic charge in the substrate.

A configuration of multistage electrode is available where electrodes are arranged in parallel on each substrate to obtain uniform high-performance plasma. The substrate is further influenced by plasma and is more likely to be charged with static electricity.

A main object of the invention is to provide a substrate treatment device and a substrate treatment method capable of eliminating static electricity in order to solve the problem of contamination caused by static electricity due to electrostatic charge on the surface of a substrate after plasma treatment.

### Means for Solving the Problems

In order to solve the problem, the invention provides a substrate treatment device comprising a standby chamber in which is arranged a transfer device for loading a substrate out of/into a cassette rack accommodating a substrate, the substrate treatment device capable of retaining the substrate transferred by the transfer device in a boat and loading, by way of a boat elevator, the boat into/out of a treatment furnace capable of applying plasma treatment to the substrate, wherein a static eliminator for eliminating static electricity of the substrate is arranged in the standby chamber.

The invention provides the substrate treatment device wherein the static eliminator is positioned in close proximity to the loading in/out port of the treatment furnace for the boat.

The invention provides the substrate treatment device wherein the start timing of the static eliminator is the timing with which the loading of the boat out of the treatment furnace is started.

The invention provides the substrate treatment device wherein the stop timing of the static eliminator is the timing with which the loading of the boat out of the treatment furnace is ended.

The invention provides the substrate treatment device wherein the static eliminator is positioned in close proximity to a path for transferring the substrate by the transfer device.

The invention provides the substrate treatment device wherein the standby chamber includes a side-cleaning unit for supplying an air flow and that the static eliminator is positioned at the upstream side of the air flow with respect to the substrate.

The invention provides the substrate treatment device wherein the static eliminator is arranged on the transfer device.

The invention provides a substrate treatment method for a substrate treatment device comprising a standby chamber in which is arranged a transfer device for loading a substrate out of/into a cassette rack accommodating a substrate, the substrate treatment device further comprising a static eliminator for eliminating static electricity of the substrate in the standby chamber, the method including steps of retaining the substrate transferred by the transfer device in a boat and loading, by way of a boat elevator, the boat into a treatment furnace capable of applying plasma treatment to the substrate, and loading the post-treatment substrate from the treatment furnace, wherein the static eliminator is positioned in close proximity to the loading in/out port of the treatment furnace for the boat, that the method detects timing with which the boat is loaded out of the treatment furnace and that the static eliminator is started to eliminate static electricity of the substrate retained in the boat when the timing is detected.

The invention detects the timing with which the loading of the boat out of the treatment furnace is ended and stops operation of the static eliminator when the timing is detected.

The substrate treatment method according to the invention provides a semiconductor manufacturing method for manufacturing a semiconductor substrate.

### BRIEF DESCRIPTION OF DRAWINGS

FIG. 1 is a plan view of a semiconductor manufacturing device according to a first embodiment of the invention.

FIG. 2 is a rear view of the semiconductor manufacturing device shown in FIG. 1.

FIG. 3 shows the variable state of tweezers.

FIG. 4 is a cross-sectional view of a treatment furnace with a boat loaded into a treatment chamber.

FIG. 5 is a plan view showing an example where a sensor is provided on the semiconductor manufacturing device according to the first embodiment.

FIG. 6 is a plan view of a semiconductor manufacturing device according to a second embodiment of the invention.

FIG. 7 is a rear view of the semiconductor manufacturing device shown in FIG. 5.

FIG. 8 is a plan view of a semiconductor manufacturing device according to a third embodiment of the invention.

FIG. 9 is a plan view of a semiconductor manufacturing device according to a fourth embodiment of the invention.

FIG. 10 is a plan view of a semiconductor manufacturing device according to a fifth embodiment of the invention.

FIG. 11 is an oblique perspective view of a treatment device applied to the invention.

FIG. 12 is a perspective view of the treatment device viewed from its side face.

### BEST MODE FOR CARRYING OUT THE INVENTION

Embodiments of the invention will be described taking a semiconductor manufacturing device as an example.

### Embodiment 1

A semiconductor manufacturing device that performs plasma treatment on a plurality of wafers as substrates to be treated will be described as a first embodiment of the invention.

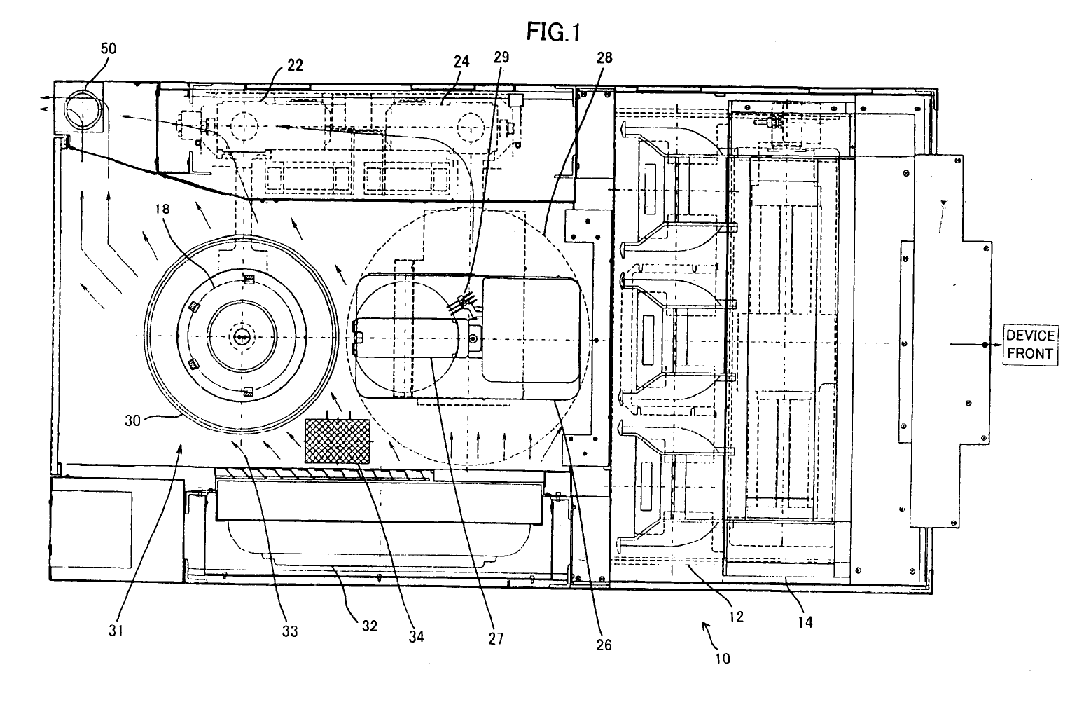

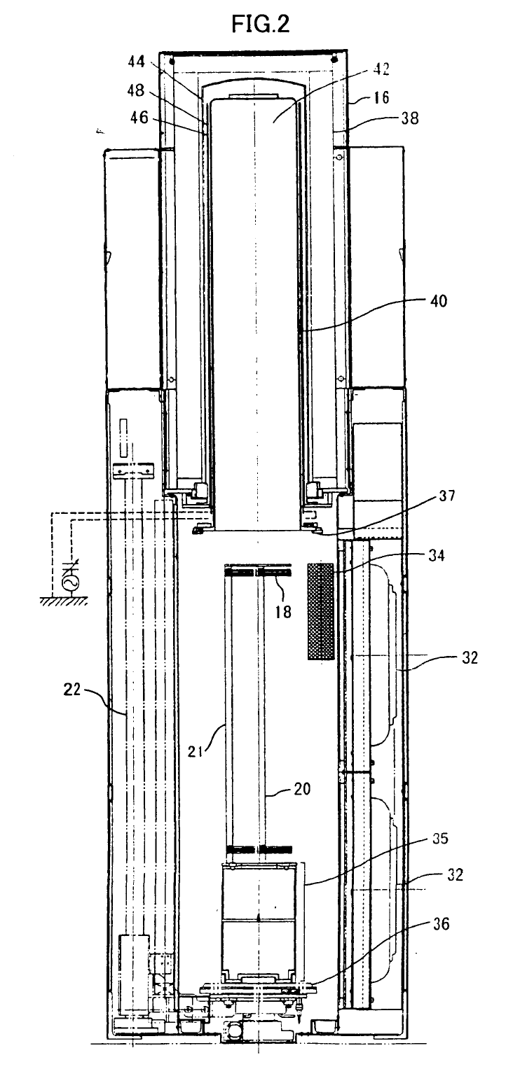

FIG. 1 is a plan view of a semiconductor manufacturing device according to the first embodiment of the invention. FIG. 2 is a rear view of the semiconductor manufacturing device shown in FIG. 1.

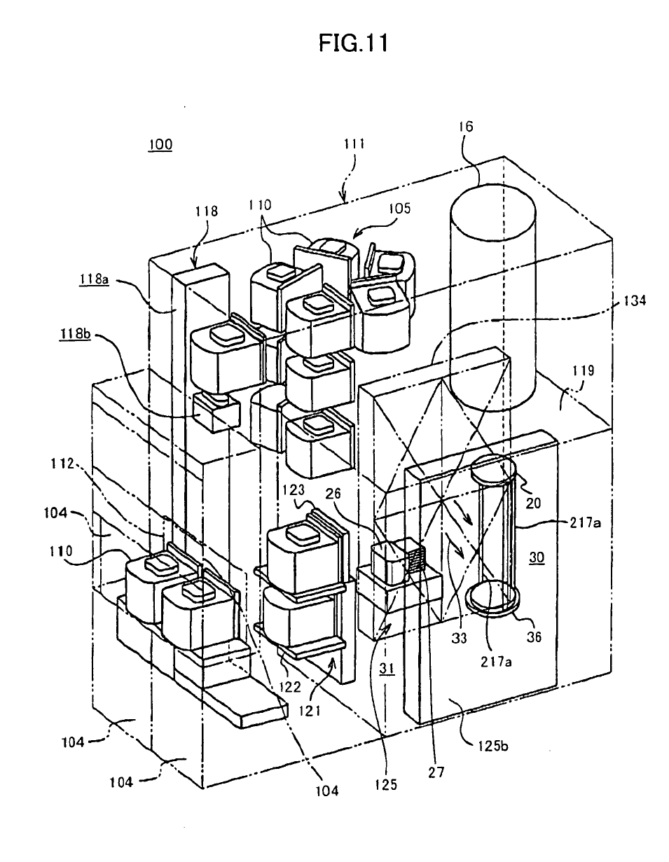

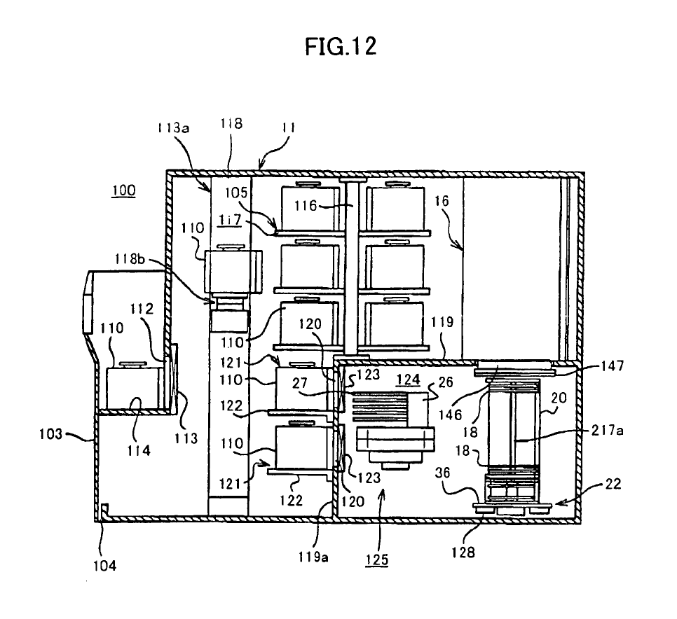

Inside an enclosure 10 is provided a cassette rack 12 at the front side. Behind the cassette rack 12 is provided a cassette elevator 14 as elevating/lowering means. The cassette track 12 as a substrate receiving container receives/consigns a cassette from/to an external transfer device shown in FIGS. 11 and 12.

In the upper area behind the enclosure 10 is provided a treatment furnace 16 below which is arranged a boat 20 for holding wafers 18 as substrates in multiple stages in horizontal posture. The boat 20 includes a boat elevator 22 for elevating/lowering the same up to/down to the treatment furnace 16. At the tip of an elevating/lowering member (that is, an arm 128 shown in FIG. 12) mounted on the boat elevator 22 is attached a seal cap 36 as a lid body, which vertically supports the boat 20 via a heat insulating holder 35 made of quartz.

In the treatment furnace 16, a heater 38 is arranged to surround a soaking tube 44, inside which is arranged an electrode tube 48 including electrodes 46 made of a conductive material and capable of applying high frequencies.

Inside the electrode tube 48 is arranged a reaction tube 40 composed of a dielectric such as quartz. The treatment chamber 42 is composed airtight of a reaction tube 40 and a seal cap 36 to form a space for treating the wafer 18. The seal cap 36 is grounded.

Between the boat elevator 22 and the cassette rack 12 is provided a transfer elevator 24 on which is mounted a wafer transfer device (substrate transfer device) 26. The wafer transfer device 26 transfers a wafer 18 between a cassette and the boat 20 with the wafer 18 placed on its tweezers 27.

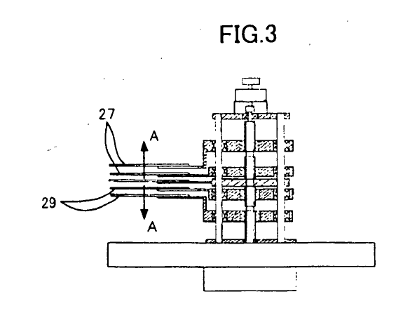

To be more precise, when the boat 20 descends to a predetermined position, the wafer transfer device 26 starts to move and loads several (for example five) wafers 18 on the tweezers 27 at a time in preset order and to carry the wafers out of the boat 20. After that, as shown by an arrow A in FIG. 3, the wafer transfer device 26 is rotated to direct the wafer to the cassette while the width of each pair of tweezers in height direction is being extended, that is, while the pitch between the tweezers 27 is being extended.

In close proximity to the tweezers 27 is provided a wafer loading recognition part 29 for detecting that the wafer 18 is loaded on the tweezers 27. The wafer loading recognition part 29 may be a fiber sensor.

A wafer transfer area 28 including the wafer transfer device 26 and a boat area 30 including the boat 20 are positioned in the standby chamber 31, which includes a side-cleaning unit 32. The side-cleaning unit 32 supplies an air flow 33 shown by an arrow in FIG. 1 to the wafer transfer area 28 and the boat area 30 so that particles will not deposit on the wafers 18 in these areas.

In close proximity to the loading in/out port for the boat 20 of the treatment furnace 16, or to be more precise, in a space close to the lower part of the loading in/out port of the treatment furnace 16 in the area between the side-cleaning unit 32 and the boat area 30 and close to the direction plate of the side-cleaning unit 32 is arranged a static eliminator 34 for eliminating static electricity of the wafer 18. This arrangement utilizes the air flow 33 from the side-cleaning unit 32 to cause charged particles generated in the static eliminator 34 to flow toward the charged post-plasma-treatment wafer 18 on the boat 20 thereby neutralizing and eliminating the static electricity with the charged particles.

At the rear of the boat elevator 22 is provided a rear fan 50. As shown by an arrow in FIG. 1, the boat elevator 22 purges the air flow 33 from the side-cleaning unit 32 to outside from the rear fan 50.

Next, the static eliminator 34 according to Embodiment 1 will be described.

A method for eliminating static electricity in atmospheric air has been commercialized as a known example by manufacturers. Thus, only the simple principle of the method will be described.

Air is composed of nitrogen, oxygen, carbon dioxide, and water vapor and turned into charged particles when ionized. Charged particles have both positive and negative polarities and. A charged particle is neutralized when absorbed to an electron having the opposite polarity. In the countermeasures against static electricity using a static eliminator, an object electrically biased to one polarity is given electric charges having the opposite polarity in order to electrically neutralize the object.

Generally speaking, static eliminators are either of corona discharge type or light irradiation type. The corona discharge type with a proven track record will be described. Corona discharge is a method for partially generating an electrical discharge at the sharp tip of an electrode needle by applying a high voltage to the needle. When an electrical discharge is generated, the air around the needle is ionized to neutralize and eliminates static electricity of the charged object.

An AC static eliminator is available on the market. The AC static eliminator generates ions through electric discharges having a positive polarity or negative polarity in a predetermined cycles in order to neutralize a charged object either with positive or negative polarity.

The term “static elimination” or “eliminating static electricity” used in this invention does not mean complete elimination of electrons charged on the wafer 18 but reduction of electrons so as not to attract impurities. For example, an absolute value of ±100V or below, or more preferably, an absolute value of ±50V or below is accepted.

Next, operation of the first embodiment of the invention will be described.

The treatment chamber 42 under atmospheric pressure elevates the boat 20 carrying a necessary number of wafers 18 by way of the boat elevator 22 and loads the boat 20 into the treatment chamber 42. The treatment chamber 42 powers up the heater 38 and heats the members in the treatment chamber 42 such as the wafer 18 and a reaction tube 40 as well as purges the gas inside the reaction tube 40.

When the wafer 18 is heated to a predetermined temperature, a reactive gas is introduced into the treatment chamber 42 and then a treatment gas is jetted toward the wafer 18. When the pressure inside the treatment chamber 42 has risen to a predetermined value, high frequency waves are applied by the electrodes 46 to turn the treatment gas into plasma thus applying plasma treatment on the wafer 18.

After the treatment, the boat elevator 22 lowers the boat 20 and the boat 20 is loaded out of treatment chamber 42. On timing with which the boat 20 exits the treatment furnace 16, the static eliminator 34 is started to eliminate static electricity of the wafer 18 on the boat 20.

Actually, the timing with which the static eliminator 34 is started is set to one of the timings (1) through (3) below.

(1) Start Timing 1

(a) The temperature in the treatment chamber 42 drops below a prespecified temperature.

(b) After the evacuation of the treatment chamber 42, a purge gas is supplied to turn the interior of the treatment chamber 42 under atmospheric pressure.

(c) Treatment of the wafer 18 is complete.

When the conditions (a) through (c) are satisfied, the static eliminator 34 is started.

(2) Start Timing 2

The boat elevator 22 has a sensor (not shown) mounted thereon. When the sensor has detected lowering operation of the boat elevator 22, that is, has detected that the boat elevator started to descend, the static eliminator 34 is started.

(3) Start Timing 3

In case a static eliminator 34 that takes time in stabilizing after it is started, the static eliminator 34 is started when the treatment gas is purged after treatment of the wafer 18.

The static eliminator 34 started with any one of the timings (1) through (3) generates charged particles, which flows to the boat area 30 in the air flow 33 from the side-cleaning unit 32. Thus, the charged particles are sequentially sprayed onto the wafers 18 sequentially passing before the static eliminator 34 with the descent of the boat 20.

In other words, the charged particles are sprayed onto the wafer 18 loaded in the lowermost slot of the boat 20 that passes first before the static eliminator 34 and static electricity is eliminated. As the boat 20 descends, static electricity of the wafers 18 loaded in the upper slots of the boat 20 are sequentially eliminated. Static electricity of all of the wafers 18 on the boat 20 are eliminated by the time the lowering operation of the boat elevator 22 is complete. Then the static eliminator 34 is stopped.

In this example, the static eliminator 34 is arranged in close proximity to the loading in/out port of the treatment furnace 16. With this arrangement, only by utilizing the loading-out operation of the boat elevator 22 following treatment, static electricity of all of the wafers 18 on the boat 20 can be eliminated. The static eliminator 34 has only to eliminate static electricity of the wafers 18 in close proximity to the loading in/out port, which allows a compact shape.

The wafer 18 loaded out of the treatment chamber 42 after wafer treatment is likely to attract more amount of impurities as time elapses. Thus, static electricity of the wafer 18 is desirably eliminated without delay after treatment. According to this method, static electricity of the wafer 18 just loaded out of the treatment chamber 42 may be eliminated, which reduces the possibility of attracting impurities.

By utilizing the air flow from the side-cleaning unit 32, it is possible to effectively eliminate static electricity of the wafer 18 on the static eliminator 34 using the air.

Moreover, the static eliminator 34 is started when or just before the boat 20 descends. This eliminate static electricity of the wafer 18 as well as a heat insulating holder 35 arranged between the boat 20 and the seal cap 36. The heat insulating holder 35 is made of quartz and is likely to be charged. When the heat insulating holder 35 is charged, the wafer 18 close to the heat insulating holder 35 could attract impurities. In case the heat insulating holder 35 has attracted impurities, plasma treatment of the heat insulating holder 35 with impurities attached in the treatment chamber 42 may generate excessive plasma close to the heat insulating holder 35 thus failing to uniform plasma generation.

Thus, static electricity of the heat insulating holder 35 is desirably eliminated. With this method, also static electricity of the heat insulating holder 35 is eliminated so that static electricity on the wafer 18 as well as in the boat 20 is eliminated. This ensures treatment with high reproducibility after repetitive treatment.

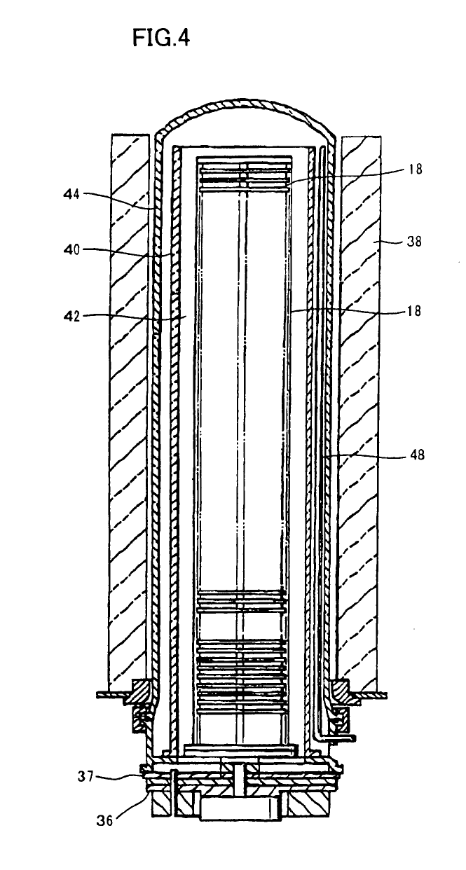

Initially, the boat 20 descends slowly, and when predetermined time has elapsed, it descends faster. The reason for this is described below. As shown in FIG. 4, an O-ring 37 on the seal cap 36 is in close contact with the reaction tube 40 while a wafer 10 is being treated. After the treatment, the O-ring 37 sticks close to the reaction tube 40 after the treatment. The boat 20 descends slowly because otherwise the boat 20 could bounce when the O-ring 37 is detached from the seal cap 36 and damage to or fracture in the wafer 18 could result.

Next, the timing with which the static eliminator 34 is stopped will be described.

Actually, the timing with which the static eliminator 34 is stopped is set to one of the timings (1) through (3) below.

(1) Stop Timing 1

The static eliminator 34 is stopped when predetermined time has elapsed after it is started.

(2) Stop Timing 2

The static eliminator 34 is stopped in accordance with the state of the boat elevator. The state is either (a) or (b) below.

(a) When the boat elevator 22 has detected a home position (initial position).

(b) When the rotation amount of the motor (not shown) of the boat elevator 22 is detected and the descent distance obtained from the rotation amount has matched a preset distance.

When one of the conditions (a) and (b) is satisfied, the static eliminator 34 is stopped.

(3) Stop Timing 3

In case a sensor for measuring a charge value to check for eliminating static electricity is provided under one of the conditions (a) and (b) and static elimination is over based on the sensor-detected value, the static eliminator 34 is stopped.

(a) Only a specific section is detected.

This is to detect a section determined as a sample. For example, as shown in FIG. 4, a sensor 52 is fixed in a position opposed to the static eliminator 34 with the boat 20 placed in between and the charge value of a wafer 18 passing before the sensor 52 is detected. This allows checkup of static elimination of the wafer 18 in an early stage.

(b) The entirety is checked.

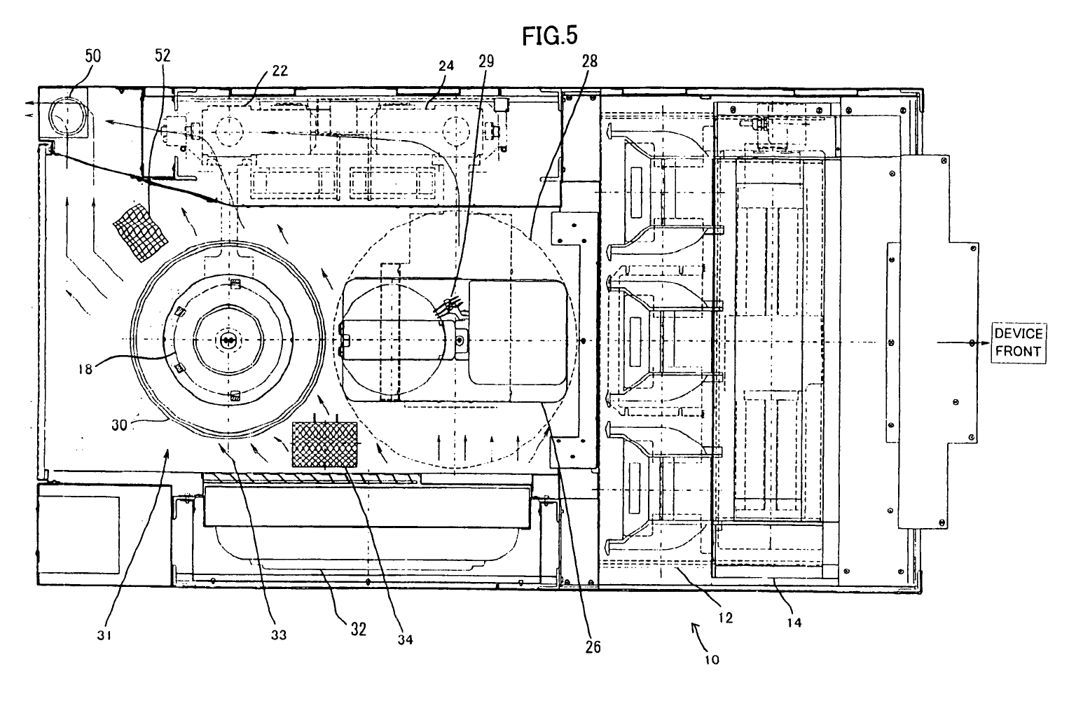

The sensor 52 detects the charge value of the wafer 18 over the total length of the boat 20. For example, as shown in FIG. 5, the sensor 52 is provided in a position opposed to the static eliminator 34 movably in vertical direction along the side face of the boat 20 with the boat 20 placed in between. This detects the charge value of the wafer 18 over the total length of the boat 20 in vertical direction, thus reliably allowing checkup of static elimination of all the wafers 18.

Another method for controlling the operation of the static eliminator 34 will be described.

As shown in FIG. 5, the sensors 52 are provided in height positions opposed to the static eliminator 34 with the boat 20 placed in between, the height positions being close to the boat 20 and respectively corresponding to a height position above the static eliminator 34 and a height position below the static eliminator 34. The sensor 52 arranged in the upper position serves to check the charging state of the wafer 18 after plasma treatment. In other words, the sensor 52 detects the charge value of the wafer 18. In case any detected charge value is greater than a preset value such as the absolute value of ±100V, the sensor 52 instructs to start the static eliminator 34.

The sensor 52 arranged in the below position serves to detect the charge value of the wafer 18 from which static electricity is eliminated by the static eliminator 34. In other words, in case the detected value detected by the sensor 52 is within a preset value set in advance such as the absolute value of ±100V, the sensor 52 assumes that static electricity of the wafer 18 has been eliminated. When checkup of all the wafers 18 is complete, the sensor 52 instructs to stop the static eliminator 34.

In this way, by using the sensor 52 capable of measuring the charge value of the wafer 18, it is possible to control a series of operations including detection of the charge value of the wafer 18 before static elimination, startup of the static eliminator 34 based on the detected value, detection of the charge value of the wafer 18 after static elimination, and stoppage of the static eliminator 34 based on the detected value after static elimination.

While detection of the charge value of the wafer 18 by the sensor 52 may be made to all the wafers 18, a simple method may include checkup of the charge value of the wafer 18 in the lowermost stage of the boat 20 before its static electricity is eliminated and checkup of the charge value of the wafer 18 in the uppermost stage of the boat 20 after its electricity is eliminated in order to start or stop the static eliminator 34.

Next, a case will be described where the boat columns 21 are an obstacle to transfer of charged particles generated on the static eliminator 34.

Charged particles generated on the static eliminator 34 are transferred in an air flow onto the wafer 18 to eliminate the static electricity on the wafer 18. In case the boat columns 21 are on its way, the boat columns 21 may act as an obstacle to the transfer. In this case, charged particles are not transferred onto the wafer 18, and as a result, static electricity of the wafer 18 may not be eliminated.

Under such a situation, the methods (a) and (b) may be used to uniformly transfer charged particles onto the wafer 18.

(a) The boat 20 is lowered while rotating.

(b) The static eliminator 34 is arranged between two adjacent boat columns 21 so that charged particles will pass between the boat columns 21.

With the methods of (a) and (b), it is possible to uniformly transfer charged particles onto a large-diameter wafer 18 as well.

In this way, operation control of startup and stoppage of the static eliminator 34 is made timely in coordination with the lowering operation of the boat 20 so that needless power is not wasted and thus power reduction is made possible.

### Embodiment 2

The second embodiment of the invention will be described referring to attached drawings.

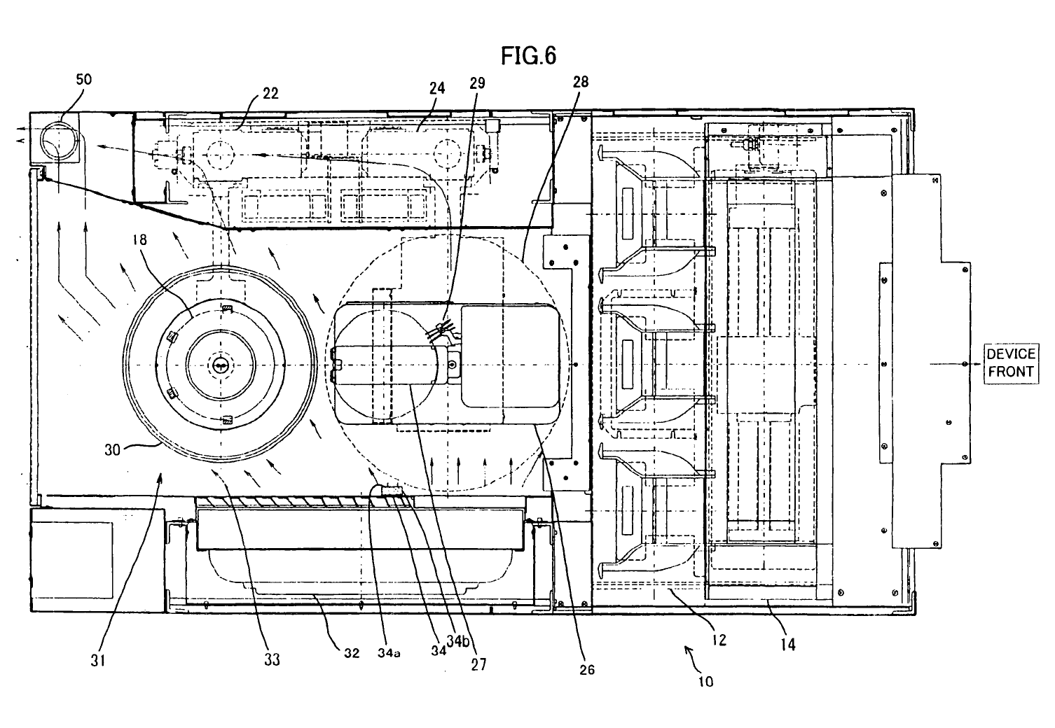

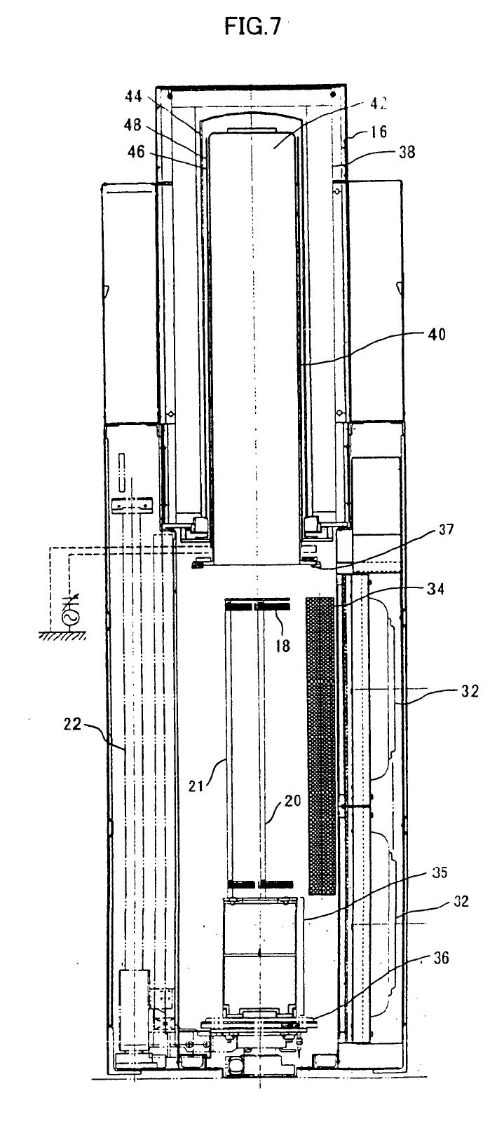

FIG. 6 is a plan view of a semiconductor manufacturing device according to a second embodiment of the invention. FIG. 7 is a rear view of the semiconductor manufacturing device shown in FIG. 6.

The static eliminator 34 eliminates static electricity of the wafer 18 loaded on the tweezers 27 of the wafer transfer device 26 from boat 20 after treatment of the wafer 18. The static eliminator 34 is mounted in a position close to the direction plate of the side-cleaning unit 32 in an orientation where its rear face 34b is opposed to the direction plate and its front face 34a is opposed to the tweezers 27.

The vertical dimension of the static eliminator 34 is almost the same as the vertical dimension of the boat 20. The static eliminator 34 is positioned so that the upper and lower ends of the static eliminator 34 will be almost the same as the height positions of the upper and lower ends of the boat 20 with the boat 20 completely lowered. This position is set to support the height position of any wafer 18 in order to adjust to the change in the position of the wafer 18 transferred on the boat by the wafer transfer device 26.

With this configuration, charged particles generated by the static eliminator 34 is transferred in the air flow coming from the side-cleaning unit 32 and issued from the rear side of the static eliminator 34 onto the wafer 18 loaded on the tweezers 27 and thereafter static electricity of the wafer 18 is eliminated.

Embodiment 2 has the same configuration as that of the first embodiment of the invention except the shape and mounting position of the static eliminator 34. Operation of Embodiment 2 except the operation control of startup and stoppage of the static eliminator 34 is the same as that of the first embodiment of the invention. Thus, description overlapping that of the configuration and operation of the first embodiment of the invention will be omitted.

Operation control of the static eliminator 34 will be described.

Actually, the timing with which the static eliminator 34 is started is set to one of the timings (1) through (3) below.

(1) Start Timing 1

When the boat 20 has reached its bottom position and the event (a) or (b) is detected, the static eliminator 34 is started.

(a) When the boat elevator 22 has detected a home position (initial position).

(b) When the rotation amount of the motor (not shown) of the boat elevator 22 is detected and the descent distance obtained from the rotation amount has matched a preset distance.

(2) Start Timing 2

When the wafer 18 is loaded on the tweezers 27.

In other words, when the wafer loading recognition part 29 has detected that the wafer 18 is loaded on the tweezers 27 after treatment of the wafer 18, the static eliminator 34 is started.

(3) Start Timing 3

When the width of the tweezers 27 in height direction is extended.

In other words, when the boat 20 descends to its bottom position, the wafer transfer device 26 starts to move and the wafer transfer device 26 loads several (for example five) wafers 18 on the tweezers 18 at a time in preset order and to carry the wafers out of the boat 20. After that, as shown in FIG. 3, each pair of tweezers 27 moves vertically so as to extend the pitch between each pair of tweezers 27. When the width of the tweezers 27 in height direction is extended, the static eliminator 34 is started.

In this way, when the pitch between the tweezers 27 is extended, charged particles generated on the static eliminator 34 are more likely to enter a space between the wafers 18, thus providing efficient static elimination.

Next, the timing with which the static eliminator 34 is stopped will be described.

Actually, the timing with which the static eliminator 34 is stopped is set to one of the timings (1) through (3) below.

(1) Stop Timing 1

The static eliminator 34 is stopped when predetermined time has elapsed after it is started.

(2) Stop Timing 2

The static eliminator 34 is stopped just before the wafer transfer device 26 loads the wafer 18 into a cassette as next step.

(3) Stop Timing 3

A sensor for measuring a charge value to check for static elimination is provided under one of the conditions (a) and (b) and in case static elimination is over, the static eliminator 34 is stopped.

(a) Only a specific section is detected.

For example, a sensor provided on the wafer transfer device 26 detects the charge value of the wafer 18 in a position determine as a sample. This allows early checkup of whether static elimination is over.

(b) The entirety is checked.

For example, a sensor is provided on the wafer transfer device 26 so as to detect the charge values of all the wafers 18 loaded on the tweezers 27. This makes it possible to check whether static electricity of all of the wafers 18 have been reliably eliminated.

### Embodiment 3

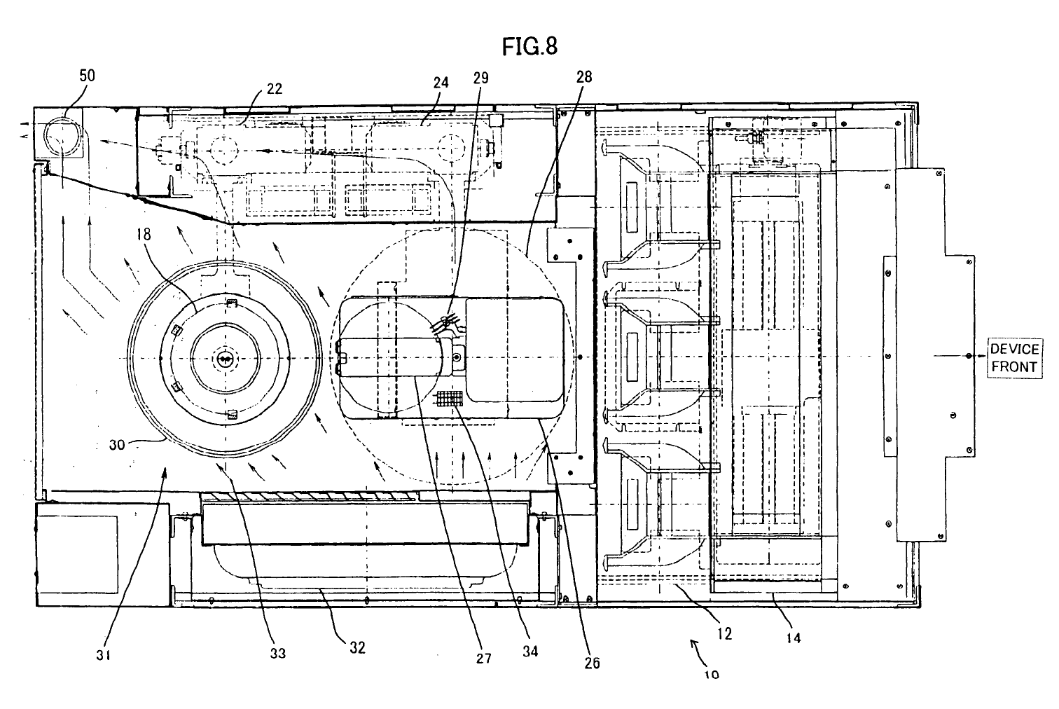

Next, the third embodiment of the invention will be described referring to attached drawings. FIG. 8 is a plan view of a semiconductor manufacturing device according to the third embodiment of the invention.

The static eliminator 34 is loaded on wafer transfer device 26. The static eliminator 34 is arranged so that the rear surface of the static eliminator 34 will be opposed to the direction plate of the side-cleaning unit 32 while the wafer transfer device 26 is rotated clockwise by 90 degrees after loading the wafer 18 on the tweezers 27 from the boat 20.

Thus, the static eliminator 34 is positioned facing the wafer 18 between the wafer 18 on the tweezers 27 and the side-cleaning unit 32. Charged particles generated on the static eliminator 34 are efficiently transferred onto the wafer 18 in the air flow 33 from the side-cleaning unit 32. In this way, static elimination of the wafers 18 is carried out with a small number of the wafers 18 thus providing accurate static elimination.

Embodiment 3 has the same configuration as that of the second embodiment of the invention except the shape and mounting position of the static eliminator 34. Operation of Embodiment 3 except the operation control of startup and stoppage of the static eliminator 34 is the same as that of the second embodiment of the invention. Thus, description overlapping that of the configuration and operation of the second embodiment of the invention will be omitted.

### Embodiment 4

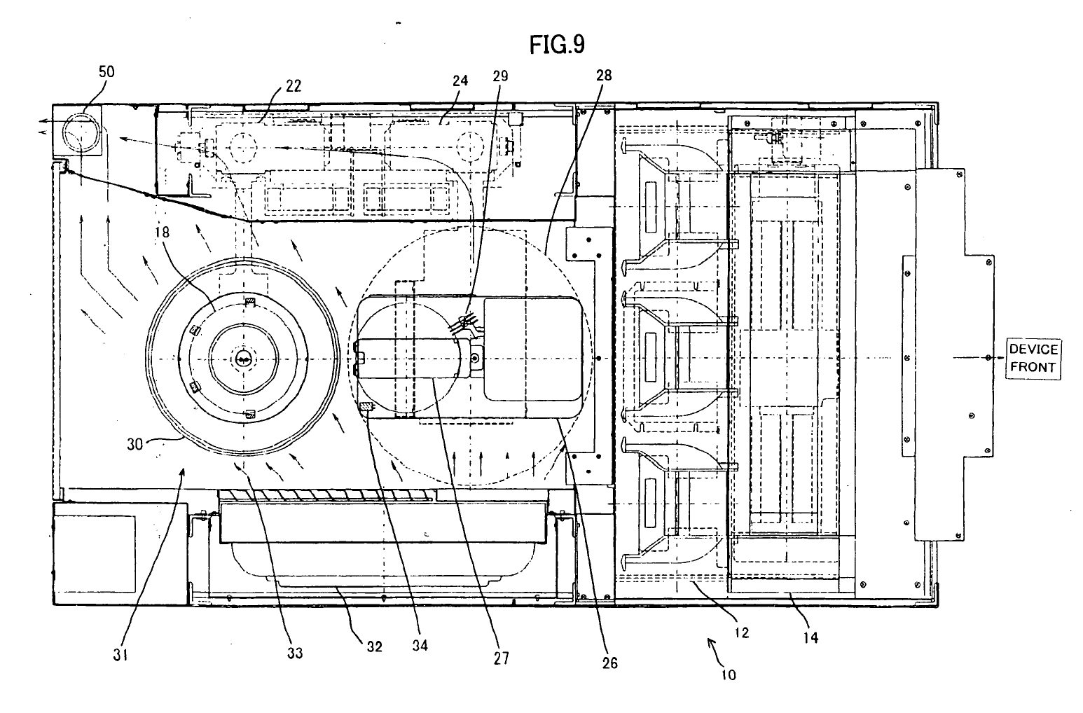

Next, the fourth embodiment of the invention will be described referring to attached drawings. FIG. 9 is a plan view of a semiconductor manufacturing device according to the fourth embodiment of the invention.

The static eliminator 34 is loaded on wafer transfer device 26. The static eliminator 34 is arranged so that the rear surface of the static eliminator 34 will be opposed to the direction plate of the side-cleaning unit 32 while the wafer transfer device 26 is rotated counterclockwise by 90 degrees after loading the wafer 18 on the tweezers 27 from the boat 20.

Thus, the static eliminator 34 is positioned facing the wafer 18 between the wafer 18 on the tweezers 27 and the side-cleaning unit 32. Charged particles generated on the static eliminator 34 are efficiently transferred onto the wafer 18 in the air flow 33 from the side-cleaning unit 32. In this way, static elimination of the wafers 18 is carried out with a small number of the wafers 18 thus providing accurate static elimination.

Embodiment 4 has the same configuration as that of the second embodiment of the invention except the shape and mounting position of the static eliminator 34. Operation of Embodiment 4 except the operation control of startup and stoppage of the static eliminator 34 is the same as that of the second embodiment of the invention. Thus, description overlapping that of the configuration and operation of the second embodiment of the invention and the operation control of the static eliminator 34 will be omitted.

### Embodiment 5

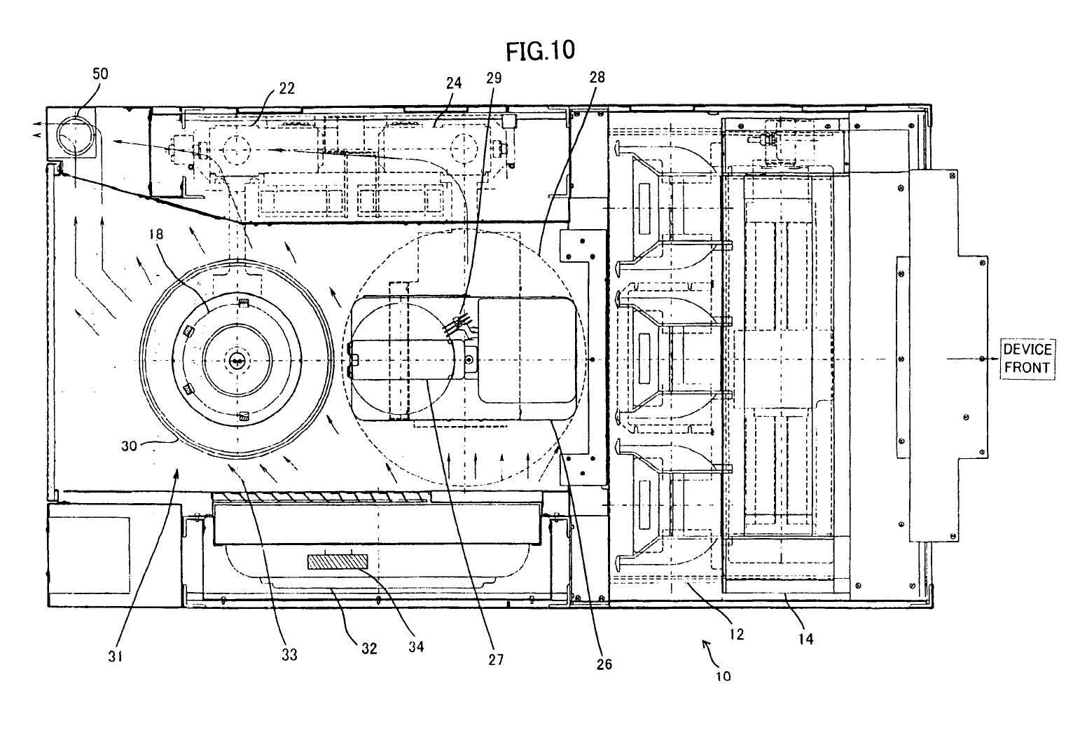

Next, the fifth embodiment of the invention will be described referring to attached drawings. FIG. 10 is a plan view of a semiconductor manufacturing device according to the fifth embodiment of the invention.

The static eliminator 34 is provided in the side-cleaning unit 32 and is arranged so that the front surface of the static eliminator will face in the same direction as that of the side-cleaning unit 32. Charged particles generated on the static eliminator 34 are transferred onto the wafer 18 in the air flow 33 from the side-cleaning unit 32 and static electricity of the wafer 18 is eliminated.

In this way, there is no need for a space for mounting the static eliminator 34 thus ensuring high efficiency of space utilization.

Embodiment 5 has the same configuration as that of the first embodiment of the invention except the shape and mounting position of the static eliminator 34. Operation of Embodiment 5 except the operation control of startup and stoppage of the static eliminator 34 is the same as that of the first embodiment of the invention. Thus, description overlapping that of the configuration and operation of the first embodiment of the invention and the operation control of the static eliminator 34 will be omitted.

Static electricity of the wafer 18 may be eliminated by transferring charged particles with the air flow 33 in the foregoing embodiments, so that a special mechanism to transfer charged particles need not be separately provided.

While only one static eliminator 34 is mounted in a single position in the foregoing embodiments, the invention is not limited thereto but a combination of one static eliminator 34 for eliminating static electricity of the wafer 18 on the boat 20 according to the first embodiment of the invention and the second embodiment of the invention and one static eliminator 34 for eliminating static electricity of the wafer 18 on the tweezers 27 according to the third embodiment of the invention and the fourth embodiment of the invention is possible. With this configuration, static elimination occurs when the boat 20 is lowered and when the wafer 18 is transferred from the boat 20, thus assuring the static elimination procedure.

In the best mode for carrying out the invention, an exemplary substrate treatment device is a semiconductor manufacturing device for performing treatment steps in a method for manufacturing a semiconductor device (IC). The following description pertains to a case where a vertical device for performing oxidization treatment, diffusion treatment or CVD treatment on a substrate (hereinafter referred to simply as the treatment device) is applied as a substrate treatment device. FIG. 11 is an oblique perspective view of a treatment device applied to the invention. FIG. 12 is a perspective view of the treatment device viewed from its side face as shown in FIG. 11.

As shown in FIGS. 11 and 12, the treatment device 100 according to this embodiment uses a hoop (substrate container; hereinafter referred to as the pod) 110 as a wafer carrier accommodating a wafer (substrate) 18 made of silicon and the like.

In the front part of the front wall 111a of the enclosure 111 of the treatment device 100 has a front maintenance port 103 as a maintenance-ready opening. Front maintenance doors 104, 104 are provided for opening/closing the front maintenance port 103.

In the front wall 111a of the enclosure 111 (corresponding to the enclosure 10 in the foregoing embodiments) is provided a pod loading in/out port (substrate container loading in/out port) 112 so as to communicate between the exterior and interior of the enclosure 111. The pod loading in/out port 112 is opened/closed by a front shutter (substrate container loading in/out port opening/closing mechanism) 113.

On the front side of the pod loading in/out port 112 is provided a load port (substrate container passing table) 114. The load port 114 is aligned with the pod 110 loaded thereon. The pod 110 is loaded onto the load port 114 by an in-process transfer device (not shown) and is loaded out of the load port 114.

In the upper area of the almost central part in the enclosure 111 in back-and-forth direction is provided a rotary pod rack (substrate container loading rack) 105 (corresponding to the cassette rack 12 in the foregoing embodiments). The rotary pod rack 105 is designed to store a plurality of pods 110 (corresponding to the cassettes in the foregoing embodiments).

In other words, the rotary pod rack 105 includes a column 116 vertically erected and intermittently rotated in a horizontal plane and a plurality of rack plates (substrate container loading tables) 117 radially supported by the column 116 at the upper, middle and lower stages. The plurality of rack plates 117 each are designed to hold a plurality of pods 110.

In the enclosure 111, a pod transfer device (substrate container transfer device) 118 is provided between the load port 114 and the rotary pod rack 105.

The pod transfer device 118 is composed of a pod elevator (substrate container elevating/lowering mechanism) 118a (corresponding to the cassette elevator 14 in the foregoing embodiments) capable of elevating/lowering while holding the pod 110 and a pod transfer mechanism (substrate container transfer mechanism) 118b as a transfer mechanism. The pod transfer device 118 is designed to transfer the pod 110 between the load port 114, the rotary pod rack 105, and a pod opener (substrate container lid body opening/closing mechanism) 121 by way of the coordinated operation of the pod elevator 118a and the pod transfer mechanism 118b.

In the lower area of the almost central part in the enclosure 111 in back-and-forth direction is provided a sub-enclosure 119 extending to the rear end. In the front wall 119a of the sub-enclosure 119 is arranged a pair of wafer loading in/out ports (substrate loading in/out ports) 120 for loading the wafer 18 into/out of the sub-enclosure 119 in upper and lower stages in vertical direction. The wafer loading in/out port 120, 120 in the upper and lower stages includes a pair of pod openers 121, 121, respectively.

The pod openers 121 include loading tables 122, 122 for loading the pod 110 and cap attaching/detaching mechanism (lid body attaching/detaching mechanism) 123, 123 for attaching/detaching the cap (lid body) of the pod 110. The pod openers 121 attaches/detaches the cap of the pod 110 loaded on the loading table 122 by way of the cap detaching mechanism to open/close the wafer loading in/out port of the pod 110.

The sub-enclosure 119 constitutes a standby chamber 31 hydraulically isolated from the spaces mounting the pod transfer device 118 and the rotary pod rack 105. In the front area of the standby chamber 31 is provided a wafer transfer mechanism (substrate transfer mechanism) 125. The wafer transfer mechanism 125 is composed of a wafer transfer device (the substrate transfer device) 125a capable of rotating or moving straight the wafer 18 in horizontal direction and a transfer elevator (substrate transfer device elevating/lowering mechanism) 24 for elevating/lowering the wafer transfer device 26.

As schematically shown in FIG. 11, the transfer elevator 24 is provided between the right end of a pressure-resistant enclosure 111 and the right end of the front area of the standby chamber 31 in the sub-enclosure 119. Successive operation of the transfer elevator 24 and the wafer transfer device 26 causes the tweezers 27 of the wafer transfer device 26 to serve as a loading part for the wafer 18 and uses the tweezers 27 to charge/discharge the wafer 18 into/out of the boat 20.

In the rear area of the standby chamber 31 is arranged a boat area 30 for accommodating the boat 20 and placing the same in standby state. As described earlier, the treatment furnace 16 is provided above the boat area 30. The lower end of the treatment furnace 16 is openable with a furnace port shutter (furnace port opening/closing mechanism) 147.

As described earlier, the treatment furnace 16 includes a treatment chamber 42. The treatment chamber 42 is partitioned airtight by a reaction tube 40 composed of a dielectric and a seal cap 36. A heater 38 is arranged to surround the reaction tube 40.

As schematically shown in FIG. 11, between the right end of the pressure-resistant enclosure 111 and the right end of the boat area of the sub-enclosure 119 is provided a boat elevator 22 for elevating/lowering the boat 20.

As shown in FIG. 12, a seal cap 36 as a lid body is horizontally mounted on the arm 128 as a coupler coupled to the platform of the boat elevator 22. The seal cap 36 is supported by the arm 128.

The seal cap 36 vertically supports the boat 20 so as to block the lower end of the treatment furnace 16. The boat includes a plurality of support members 217a as described later.

When the arm 128 is elevated by the boat elevator 22 and the seal cap 36 closes the treatment chamber 42 of the treatment furnace 16, the boat 20 is inserted into or loaded into the treatment chamber. When the arm 128 is lowered by the boat elevator 22, the boat 20 is loaded out of the treatment chamber 42.

As schematically shown in FIG. 11, at the left end of the standby chamber 31 facing the transfer elevator 24 and opposite to the boat elevator 22 are provided a side-cleaning unit 32 composed of a supply fan and a dustproof filter for supplying an air flow 33 being a purified atmosphere or an inert gas. Between the wafer transfer device 26 and the side-cleaning unit 32 is provided a notch alignment device (not shown) as a substrate aligning device for aligning the positions of wafers in circumferential direction.

The air flow 33 issued from the side-cleaning unit 32 is circulated into the notch alignment device, the wafer transfer device 26 and the boat 20 in the boat area 30 and then taken into a duct (not shown) and purged outside the enclosure 111 or circulated to the primary side (supply side) as the intake side of the side-cleaning unit 32 and then jetted into the standby chamber 31 by the side-cleaning unit 32 again. Such a configuration keeps clean the standby chamber.

Operation of the treatment device in this example will be described.

As shown in FIGS. 11 and 12, when the pod 110 is supplied to the load port 114, the pod loading in/out port 112 is opened by a front shutter 113. The pod 110 on the load port 114 is loaded in of the pod loading in/out port 112 into the enclosure 111 by the pod transfer device 118.

The pod 110 thus loaded into the enclosure is automatically transferred and passed to a specified rack plate 117 of the rotary pod rack 105 by the pod transfer device 118. The pod 110 is temporarily stored on the rack plate 117 and is transferred to one pod opener 121 from the rack plate 117 and placed on the loading table 122 or directly transferred to the pod opener 121 and transferred to the loading table 122. In this example, the wafer loading in/out port 120 of the pod opener 121 is closed by the cap attaching/detaching mechanism 123, with the air flow 22 circulating into and filling the standby chamber 31. For example, the standby chamber 31 is filled with a nitrogen gas as an air flow 33 so that the oxygen concentration is equal to or below 20 ppm, a value considerably lower than that inside the enclosure 111 (atmospheric air).

The pod 110 placed on the loading table 122 has its opening-side end surface pressed against the opening edge of the wafer loading in/out port 120 in the front wall 119a of the sub-enclosure 119 and its cap removed by the cap attaching/detaching mechanism 123 with the wafer loading in/out port left open.

When the pod 110 is opened by the pod opener 121, the wafer 18 is picked up by the tweezers 27 of the wafer transfer device 26 from the pod 110 via the wafer loading in/out port. The pod 100 is loaded into the boat area 30 behind the standby chamber 31 after wafer alignment by the notch alignment device 135 and is charged into the boat 20. Having passed the wafer 18 to the boat 20, the wafer transfer device 26 returns to the pod 110 and charges the next wafer 18 into the boat 20.

During the process of charging a wafer into the boat 20 by the wafer transfer device 26 in one (upper or lower) pod opener 121, another pod 110 is transferred to and placed on the other (lower or upper) pod opener 121 from the rotary pod rack 105 by the pod transfer device 118, with the process of opening the pod 110 by the pod opener 121 concurrently being under way.

When a predetermined number of wafers 18 are charged into the boat 20, the lower end of the treatment furnace 16 closed by the furnace port shutter 147 is opened by the furnace port shutter 147. Next, the boat 20 holding a group of wafers 18 is loaded into the treatment furnace 16 as the seal cap 36 is elevated by the boat elevator 22.

After loading, the wafers 18 are subjected to arbitrary treatment in the treatment furnace 16.

After the treatment, the wafers 18 and the pod 110 are dispensed outside the enclosure 111 in almost the reverse procedure of the above-mentioned except the wafer alignment step in the notch alignment device 135.

According to the embodiment of the invention detailed above, it is possible to eliminate, by using a static eliminator, static electricity of a substrate in the standby chamber into which a substrate just after plasma treatment in the treatment furnace is loaded. This reliably eliminates static electricity on the post-plasma-treatment substrate without delay. This minimizes deposition of contamination caused by charging of static electricity.

While a static eliminator is provided in the standby chamber in the embodiment of the invention, the problems described below will result in case a static eliminator is provided outside the standby chamber. It is thus further desirable to perform static elimination in the standby chamber.

(Problem 1)

In the space of the enclosure 11 except the standby chamber, the wafer 18 is already stored in the pod 110. Same as the standby chamber, the interior of the pod is kept in a clean state and isolated from the outer space.

In case charged particles are loaded into the pod by the static eliminator, it is necessary to open the pod. In this way, the wafer in the pod is exposed to outside air thus causing suspended solids in the outside air to deposit on the substrate and possibly contaminating the wafer.

(Problem 2)

As described above, it is necessary to reliably eliminate static electricity on a substrate after plasma treatment without delay.

In case a static eliminator is provided outside the standby chamber, it is clear that it takes more time to start static elimination than when a static eliminator is provided in the standby chamber. Even a pod in the clean state could attract particles.

Substrates loaded out of the treatment furnace after plasma treatment sequentially passes and their static electricity is eliminated before the static eliminator positioned in close proximity to the loading in/out port of the treatment furnace, which reliably eliminates static electricity on the substrate without delay. Further, this minimizes deposition of contamination caused by charging of static electricity.

The static eliminator is arranged in close proximity to the loading in/out port of the treatment furnace. Thus, all the substrates pass before the static eliminator only when a boat is loaded. This allows a compact static eliminator to support static elimination of all the substrates. This also suppresses the in-device occupancy and reducing related costs.

Further, the start timing with which the static eliminator starts static elimination is the start timing of loading a substrate out of the treatment furnace. This starts the static eliminator only when static electricity of a substrate needs to be eliminated. As a result, needless power is not wasted and thus power reduction is made possible.

Further, the end timing with which the static eliminator ends static elimination is the stop timing of loading a substrate out of the treatment furnace. The static eliminator is active only when it is necessary to eliminate static electricity of a substrate. As a result, needless power is not wasted and thus power reduction is made possible.

It is possible to eliminate static electricity of a substrate in the process where a substrate just after plasma treatment is loaded. This efficiently and reliably eliminates static electricity on the post-plasma-treatment substrate. Further, this minimizes deposition of contamination caused by charging of static electricity.

The static eliminator and the substrate are respectively positioned upstream of the airflow issued from the side-cleaning unit and downstream thereof. Charged particles generated on the static eliminator are transferred in an air flow toward a substrate thus eliminating the static electricity on the substrate. This efficiently eliminates static electricity of a substrate by way of a static eliminator using air. There is no need to separately provide a charged particles transfer mechanism.

A small number of substrates loaded on the wafer transfer device are subjected to static elimination thus ensuring accurate static elimination. This minimizes deposition of contamination caused by charging of static electricity.

The static eliminator is started only when it is necessary to eliminate static electricity of a substrate, that is, only when a boat is loaded out of the treatment furnace. As a result, needless power is not wasted and thus power reduction is made possible.

According to the embodiments of the invention, the static eliminator is stopped and static elimination of a substrate is complete with the timing loading of a boat out of the treatment furnace is ended. Thus, the static eliminator is active only when it is necessary to eliminate static electricity of a substrate. As a result, needless power is not wasted and thus power reduction is made possible.

### INDUSTRIAL APPLICABILITY

As described above, the invention provides a substrate treatment device and a substrate treatment method capable of eliminating static electricity in order to solve the problem of contamination caused by static electricity on the surface of a substrate after plasma treatment.

1. A substrate treatment device comprising a standby chamber in which is arranged a transfer device for loading a substrate out of/into a cassette rack accommodating a substrate, said substrate treatment device capable of retaining said substrate transferred by the transfer device in a boat and loading, by way of a boat elevator, the boat into/out of a treatment furnace capable of applying plasma treatment to said substrate, wherein a static eliminator for eliminating static electricity of said substrate is arranged in said standby chamber.

2. The substrate treatment device according to claim 1, wherein said static eliminator is positioned in close proximity to the loading in/out port of the treatment furnace for said boat.

3. The substrate treatment device according to claim 2, wherein the start timing of said static eliminator is the timing with which the loading of said boat out of said treatment furnace is started.

4. The substrate treatment device according to claim 2, wherein the stop timing of said static eliminator is the timing with which the loading of said boat out of said treatment furnace is ended.

5. The substrate treatment device according to claim 1, wherein said static eliminator is positioned in close proximity to a path for transferring said substrate by said transfer device.

6. The substrate treatment device according to claim 1, wherein said standby chamber includes a side-cleaning unit for supplying an air flow and that said static eliminator is positioned at the upstream side of said air flow with respect to said substrate.

7. The substrate treatment device a according to claim 1, wherein said static eliminator is arranged on said transfer device.

8. A substrate treatment method for a substrate treatment device comprising a standby chamber in which is arranged a transfer device for loading a substrate out of/into a cassette rack accommodating a substrate, said substrate treatment device further comprising a static eliminator for eliminating static electricity of said substrate in the standby chamber,
said method including steps of retaining said substrate transferred by the transfer device in a boat and loading, by way of a boat elevator, the boat into a treatment furnace capable of applying plasma treatment to said substrate, and loading the post-treatment substrate from the treatment surface, wherein
said static eliminator is positioned in close proximity to the loading in/out port of the treatment furnace for said boat, that said method detects timing with which said boat is loaded out of said treatment furnace and that
said static eliminator is started to eliminate static electricity of said substrate retained in said boat when said timing is detected.

9. The substrate treatment method according to claim 8, said method detecting the timing with which the loading of said boat out of said treatment furnace is ended and stopping operation of said static eliminator when said timing is detected.

10. A semiconductor manufacturing method for manufacturing a semiconductor substrate by way of the substrate treatment method according to claim 8.
